(19) United States
(12) Patent Application Publication
(10) Pub. No.: US 2026/0206405 A1
(43) Pub. Date: Jul. 16, 2026

(54) LIGHT-EMITTING DEVICE AND PREPARATION METHOD THEREFOR

(71) Applicant: TCL Technology Group Corporation, Huizhou, Guangdong (CN)

(72) Inventor: Wenjun HOU, Huizhou, Guangdong (CN)

(73) Assignee: TCL Technology Group Corporation, Huizhou, Guangdong (CN)

(21) Appl. No.: 19/137,638

(22) PCT Filed: Oct. 27, 2023
(86) PCT No.: PCT/CN2023/127323

§ 371 Date: Jun. 10, 2025

(30) Foreign Application Priority Data
Dec. 14, 2022 (CN) 202211610516.9

(51) Int. Cl. H10K 50/115; H10K 50/13; H10K 50/15; H10K 50/16; H10K 50/17; H10K 50/19; H10K 102/00

(52) U.S. Cl. CPC H10K 50/115; H10K 50/13; H10K 50/15; H10K 50/16; H10K 50/171; H10K 50/19; H10K 2102/351

(57) ABSTRACT

Disclosed are a light-emitting device and a preparation method therefor, and a display device. The light-emitting device includes a first electrode, a first light-emitting unit, one or more charge generation layers, a second light-emitting unit, an electron transport layer and a second electrode, which are sequentially stacked. A charge generation layer is arranged between two light-emitting units, and no hole transport layer is arranged, thereby simplifying the structure of a light-emitting device while ensuring the brightness, and reducing the overall thickness of the light-emitting device.

The present disclosure claims priority to the Chinese patent application No. 202211610516.9, filed on Dec. 14, 2022, and entitled “LIGHT-EMITTING DEVICE, PREPARATION METHOD THEREFOR, AND DISPLAY DEVICE”, the content of which is incorporated herein by reference in its entirety.

### TECHNICAL FIELD

The present disclosure relates to the technical field of display, in particular to a light-emitting device, a preparation method therefor, and a display device.

### BACKGROUND

Quantum dots have been widely used in quantum dot light-emitting diodes (QLED) due to their unique optical properties, such as continuous tunable emission wavelength with size and composition, narrow emission spectrum, high fluorescence efficiency, and good stability. The QLED device structure mainly includes an anode, a hole functional layer, a light-emitting layer, an electron functional layer, and a cathode. Under the action of an electric field, the holes generated by the anode of the QLED device migrate to the light-emitting layer, and the electrons generated by the cathode also migrate to the light-emitting layer. When the holes and electrons meet in the light-emitting layer, energy excitons are generated, thereby exciting the quantum dots to finally produce visible light.

In order to further improve the screen brightness and product life of the quantum dot light-emitting diode, a stacked device can be produced by increasing the number of light-emitting layers between the anode and the cathode. However, when the light-emitting layers are stacked in the current stacked device, the light-emitting layers and the hole functional layers and the electron functional layers adjacent thereto need to be stacked together, which causes the final structure of the stacked device to be complex and the thickness to be thick, and it is difficult to meet the requirements of device thickness thinning and device structure simplification.

### Technical Solution

The present disclosure provides a light-emitting device, a preparation method therefor, and a display device.

The present disclosure provides a light-emitting device, including:
a first electrode, a first light-emitting unit, one or more charge generation layers, a second light-emitting unit, an electron-transporting layer, and a second electrode, which are sequentially stacked; where a material of the charge generation layer includes an n-type metal oxide.

In some embodiments, the material of the charge generation layer consists of the n-type metal oxide. Therefore, each charge generation layer does not contain a p-type material.

In some embodiments, the material of the charge generation layer is selected from one or more of ZnO, Znₓ₁Mg_{y1}O, Znₓ₁Al_{y1}O, SnO₂, Znₓ₁Sn_{y1}O, Znₓ₂Mg_{y2}Li_{z2}O, x1+y1=1 or x2+y2+z2=1.

In some embodiments, for x1+y1=1, 0.8≤x1≤0.95; and/or

$$for x 2 + y 2 + z 2 = 1 , 0.8 \leq x 2 \leq 0.95 .$$

In some embodiments, the material of the charge generation layer is selected from one or more of ZnO, Znₓ₁Mg_{y1}O, Znₓ₁Al_{y1}O, SnO₂, Znₓ₁Sn_{y1}O, and Znₓ₂Mg_{y2}Li_{z2}O, where x1+y1=1 or x2+y2+z2=1.

In some embodiments, the material of the charge generation layer is selected from one or more of Zn_{0.95}Mg_{0.050}, Zn_{0.9}Mg_{0.10}, Zn_{0.85}Mg_{0.15}O, Zn_{0.95}Al_{0.05}O, Zn_{0.9}Al_{0.1}O, Zn_{0.85}Al_{0.15}O, Zn_{0.95}Sn_{0.05}O, Zn_{0.9}Sn_{0.10}, Zn_{0.85}Sn_{0.15}O, and Zn_{0.9}Mg_{0.5}Li_{0.5}O.

In some embodiments, a number of layers of the charge generation layer is 1 to 3.

In some embodiments, a thickness of the charge generation layer is 20 to 60 nm.

In some embodiments, an average particle size of the material of the charge generation layer is 4 to 30 nm.

In some embodiments, a conduction band minimum energy level of the n-type metal oxide is less than or equal to −3.5 eV.

In some embodiments, a valence band maximum energy level of the second light-emitting layer is greater than or equal to −5.4 eV and less than −3.5 eV.

In some embodiments, the first light-emitting unit and the second light-emitting unit independently include one or more light-emitting layers which are stacked. For example, the first light-emitting unit may include one or more layers of first light-emitting layers disposed in a stack. A number of layers of the first light-emitting layers may be 1 to 3. The second light-emitting unit may include one or more layers of second light-emitting layers disposed in a stack. A number of layers of the second light-emitting layers may be 1 to 3. In some embodiments, a thickness of the second light-emitting layer is 10 to 50 nm.

In some embodiments, when the second light-emitting unit includes the second light-emitting layer, a material of the second light-emitting layer includes a second quantum dot.

In some embodiments, an emission wavelength of the second quantum dot may be 615 to 625 nm, 535 to 555 nm, or 465 to 480 nm. Specifically, the second quantum dot may include a second red quantum dot having an emission wavelength of 615 to 625 nm. The second quantum dot may include a second green quantum dot having an emission wavelength of 535 to 555 nm. The second quantum dot may include a second blue quantum dot having an emission wavelength of 465 to 480 nm.

In some embodiments, the material of the second quantum dot includes one or more of InN, InP, InAs, InSb, InPAs, InPSb, copper indium sulfide (CIS), copper indium gallium sulfide (CIGS), and zinc copper indium sulfide (ZCIS).

In some embodiments, an average particle size of the second quantum dot is 5 to 30 nm.

In some embodiments, when the first light-emitting unit includes the first light-emitting layer, a material of the first light-emitting unit includes one or more of an organic light-emitting material, a first quantum dot, and a perovskite semiconductor nanoparticle.

In some embodiments, a thickness of the first light-emitting unit is 10-50 nm.

In some embodiments, the organic light-emitting material includes one or more of a diaryl anthracene derivative, a stilbene aromatic derivative, a pyrene derivative, or a fluorene derivative, a blue-emitting TBPe fluorescent material, a green-emitting TTPA fluorescent material, an orange-emitting TBRb fluorescent material, and a red-emitting DBP fluorescent material.

In some embodiments, the first quantum dot is selected from one or more of a single-structure quantum dot and a core-shell structure quantum dot; a material of the single-structure quantum dot, a core material of the core-shell structure quantum dot, and a shell material of the core-shell structure quantum dot are respectively selected from, but not limited to, one or more of a group II-VI compound, a group IV-VI compound, a group III-V compound, and a group I-III-VI compound.

In some embodiments, the group II-VI compound is selected from, but not limited to, one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe.

In some embodiments, the group IV-VI compound is selected from, but not limited to, one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe.

In some embodiments, the group III-V compound is selected from, but not limited to, one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb.

In some embodiments, the group I-III-VI compound is selected from, but not limited to, one or more of CuInS₂, CuInSe₂, and AgInS₂.

In some embodiments, the perovskite semiconductor nanoparticle is selected from one or more of a doped or undoped inorganic perovskite semiconductors, or an organic-inorganic hybrid perovskite semiconductor.

In some embodiments, the inorganic perovskite semiconductor has a general structure of AMX₃, wherein A is a Cs⁺ ion, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is a halide anion selected from one or more of Cl, Br, I.

In some embodiments, the organic-inorganic hybrid perovskite semiconductor has a general structure of BMX₃, wherein B is an organic amine cation selected from CH₃(CH₂)ₙ₋₂NH₃⁺ or [NH₃(CH₂)ₙNH₃]²⁺, wherein n>2, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is a halide anion selected from one or more of Cl⁻, Br⁻, I⁻.

In some embodiments, an average particle size of the first quantum dots is 5-30 nm.

In some embodiments, an average particle size of the perovskite semiconductor nanoparticles is 15-40 nm.

In some embodiments, the first electrode and the second electrode are independently selected from a metal electrode, a carbon electrode, a doped or undoped metal oxide electrode, and a composite electrode; the metal electrode is made of one or more of Al, Ag, Cu, Mo, Au, Ba, Ca, and Mg; the carbon electrode is made of one or more of graphite, carbon nanotube, graphene, and carbon fiber; the doped or undoped metal oxide electrode is made of one or more of ITO, FTO, ATO, AZO, GZO, IZO, MZO, and AMO; and the composite electrode is made of one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS.

In some embodiments, a material of the electron transport layer includes one or more of an inorganic nanocrystalline material, a doped inorganic nanocrystalline material, and an organic material; the inorganic nanocrystalline material includes one or more of zinc oxide, titanium dioxide, tin dioxide, aluminum oxide, calcium oxide, silicon dioxide, gallium oxide, zirconium oxide, nickel oxide, and zirconium sesquioxide; the doped inorganic nanocrystalline material is an inorganic nanocrystalline material containing a doping element, and the doping element is one or more of Mg, Ca, Li, Ga, Al, Co, and Mn; and the organic material includes one or both of polymethyl methacrylate and polyvinyl butyral.

In some embodiments, the material of the electron transport layer is selected from one or more of ZnO, Znₓ₁Mg_{y1}O, Znₓ₁Al_{y1}O, SnO₂, Znₓ₁Sn_{y1}O, and Znₓ₂Mg_{y2}Li_{z2}O, wherein x1+y1=1 or x2+y2+z2=1.

In some embodiments, the material of the electron transport layer is selected from one or more of Zn_{0.95}Mg_{0.050}, Zn_{0.9}Mg_{0.10}, Zn_{0.85}Mg_{0.15}O, Zn_{0.95}Al_{0.05}O, Zn_{0.9}Al_{0.1}O, Zn_{0.85}Al_{0.15}O, Zn_{0.95}Sn_{0.050}, Zn_{0.9}Sn_{0.10}, Zn_{0.85}Sn_{0.15}O, and Zn_{0.9}Mg_{0.5}Li_{0.5}O.

In some embodiments, a thickness of the electron transport layer is 20-60 nm.

In some embodiments, the optoelectronic device further includes a hole functional layer between the first electrode and the first light-emitting unit, where the hole functional layer includes one or both of a hole injection layer and a hole transport layer. When the hole functional layer includes the hole injection layer and the hole transport layer, the hole injection layer is disposed on the side close to the first electrode, and the hole transport layer is disposed on the side close to the first light-emitting unit.

In some embodiments, the optoelectronic device further includes an electron injection layer, which is disposed between the electron transport layer and the second electrode and is close to the second electrode.

In some embodiments, the first electrode is an anode. A thickness of the first electrode is 50-110 nm.

In some embodiments, the second electrode is a cathode. A thickness of the second electrode is 80-160 nm.

In some embodiments, a material of the hole injection layer is selected from one or more of PEDOT:PSS, F4-TCNQ, HATCN, CuPc, MCC, a transition metal oxide, and a transition metal chalcogenide; where the transition metal oxide includes one or more of NiO, MoO₂, WO₃, and CuO; and the transition metal chalcogenide includes one or more of MoS₂, MoSe₂, WS₃, WSe₃, and CuS.

In some embodiments, a thickness of the hole injection layer is 10-50 nm.

In some embodiments, a material of the hole transport layer is selected from one or more of TFB, PVK, poly-TPD, PFB, TCATA, CBP, TPD, NPB, PEDOT:PSS, TPH, TAPC, Spiro-NPB, Spiro-TPD, doped or undoped NiO, MoO₃, WO₃, V₂O₅, P-type gallium nitride, CrO₃, CuO, MoS₂, MoSe₂, WS₃, WSe₃, CuS, and CuSCN.

In some embodiments, a thickness of the hole transport layer is 15-50 nm.

In some embodiments, a material of the electron injection layer includes one or more of LiF/Yb, RbBr, ZnO, Ga₂O₃, Cs₂CO₃, and Rb₂CO₃.

In some embodiments, a thickness of the electron injection layer is 15-30 nm.

The disclosure provides a method for preparing a light-emitting device, including:
providing a first electrode and a first light-emitting unit stacked;
providing a charge generation liquid containing an n-type metal oxide, and disposing the charge generation liquid on the first light-emitting unit to obtain one or more charge generation layers; and
forming a second light-emitting unit, an electron transport layer, and a second electrode on the charge generation layer in sequence to obtain the light-emitting device.

The disclosure provides another method for preparing a light-emitting device, including:
providing a second electrode, an electron transport layer, and a second light-emitting unit stacked;
providing a charge generation liquid containing an n-type metal oxide, and disposing the charge generation liquid on the second light-emitting unit to obtain one or more charge generation layers; and
forming a first light-emitting unit and a first electrode on the charge generation layer to obtain the light-emitting device.

In some embodiments, a number of the charge generation layers is 1-3.

In some embodiments, a conduction band minimum energy level of the n-type metal oxide is less than or equal to −3.5 eV. The minimum value of the conduction band minimum energy level of the n-type metal oxide is a valence band maximum energy level of the second light-emitting unit, i.e. greater than or equal to −5.4 eV.

In some embodiments, a material of the charge generation layer includes one or more of ZnO, Znₓ₁Mg_{y1}O, Znₓ₁Al_{y1}O, SnO₂, Znₓ₁Sn_{y1}O, Znₓ₂Mg_{y2}Li_{z2}O, where x1+y1=1 or x2+y2+z2=1.

In some embodiments, the first light-emitting unit includes a first light-emitting layer, and a material of the first light-emitting layer includes one or more of an organic light-emitting material, a first quantum dot, and a perovskite semiconductor nanoparticle.

In some embodiments, the second light-emitting unit includes a second light-emitting layer, and a material of the second light-emitting layer includes a second quantum dot, and a material of the second quantum dot is selected from one or more of InN, InP, InAs, InSb, InPAs, InPSb, copper indium sulfide (CIS), copper indium gallium sulfide (CIGS), and zinc copper indium sulfide (ZCIS).

In some embodiments, the valence band maximum energy level of the second light-emitting layer is greater than or equal to −5.4 eV and less than −3.5 eV.

Some embodiments of the present disclosure also provide a display device including the light-emitting device as described in any of the above embodiments or prepared by the method for preparing the light-emitting device according to any of the above embodiments.

The light-emitting device provided by embodiments of the present disclosure includes a first electrode, a first light-emitting unit, one or more charge generation layers, a second light-emitting unit, an electron transport layer, and a second electrode which are stacked in sequence. The present disclosure sets the charge generation layer containing the n-type metal oxide between the two light-emitting units and does not set a hole transport layer. Since the n-type metal oxide is conducive to the transmission of holes and electrons and the recombination in the two light-emitting units, the light-emitting device of the present disclosure simplifies the structure of the light-emitting device and reduces the overall thickness under the condition of ensuring the luminance.

### BRIEF DESCRIPTION OF DRAWINGS

In order to more clearly illustrate the technical solutions in the embodiments of the present disclosure, the following briefly introduces the drawings required in the embodiment description. Obviously, the drawings described below are merely some embodiments of the present disclosure, and other drawings can be obtained by those skilled in the art without creative effort.

FIG. 1 is a schematic structural diagram of a light-emitting device according to a first embodiment of the present disclosure.

FIG. 2 is a schematic structural diagram of a light-emitting device according to a second embodiment of the present disclosure.

FIG. 3 is a schematic structural diagram of a light-emitting device according to a third embodiment of the present disclosure.

FIG. 4 is a schematic structural diagram of a light-emitting device according to a fourth embodiment of the present disclosure.

FIG. 5 is a flow chart of a first preparation method of a light-emitting device according to the present disclosure.

FIG. 6 is a flow chart of a second method for preparing a light-emitting device according to the present disclosure.

FIG. 7 is a flow chart of a method for preparing a light-emitting device according to Example 1 of the present disclosure.

FIG. 8 is a schematic structural diagram of Comparative Example 1 of a light-emitting device according to the present disclosure.

In the drawings, the reference numerals indicate:
100—light-emitting device, 10—first electrode, 20—first light-emitting unit, 30—charge generation layer, 40—second light-emitting unit, 50—electron transport layer, 60—second electrode, 70—hole injection layer, 80—hole transport layer.

### DETAILED DESCRIPTION

The technical solutions in the embodiments of the present disclosure will be clearly and completely described below with reference to the drawings in the embodiments of the present disclosure. Obviously, the described embodiments are only part but not all of the embodiments of the present disclosure. Based on the embodiments of the present disclosure, all other embodiments obtained by a person of ordinary skill in the art without creative effort should belong to the scope of the present disclosure.

The embodiments of the present disclosure provide a light-emitting device, a preparation method therefor, and a display device. The following respectively describes the details. It should be noted that the description order of the following embodiments is not used as a limitation on the preferred order of the embodiments. In addition, in the description of the present disclosure, the term “comprising” means “including but not limited to”. The terms first, second, third, etc. are only used as labels and do not impose numerical requirements or establish an order.

In the present disclosure, “and/or” describes an association relationship of associated objects, and indicates that three relationships can exist, for example, A and/or B can indicate that A exists alone, A and B exist simultaneously, and B exists alone. A and B can be singular or plural.

In the present disclosure, “one or more” and the like refer to one or more of the listed items, and “multiple” refers to any combination of two or more of the items, including any combination of a single item or multiple items. For example, “at least one of a, b, or c” or “at least one of a, b, and c” can represent a, b, c, a-b (that is, a and b), a-c, b-c, or a-b-c, where a, b, and c can be single or multiple.

It is to be understood that the description in terms of a range is merely provided for the sake of convenience and brevity, and should not be construed as a limitation of the scope of the disclosure; therefore, it should be considered that the range description has specifically disclosed all possible sub-ranges and single values within the range. For example, it should be considered that the range description from 0.04 to 0.1 has specifically disclosed sub-ranges, such as from 0.04 to 0.05, from 0.05 to 0.06, from 0.06 to 0.07, from 0.07 to 0.09, etc., as well as single values within the range, such as 0.04, 0.05, and 0.06, regardless of the range. In addition, whenever a numerical range is indicated herein, it is meant to include any cited numeral (fractional or integral) within the indicated range.

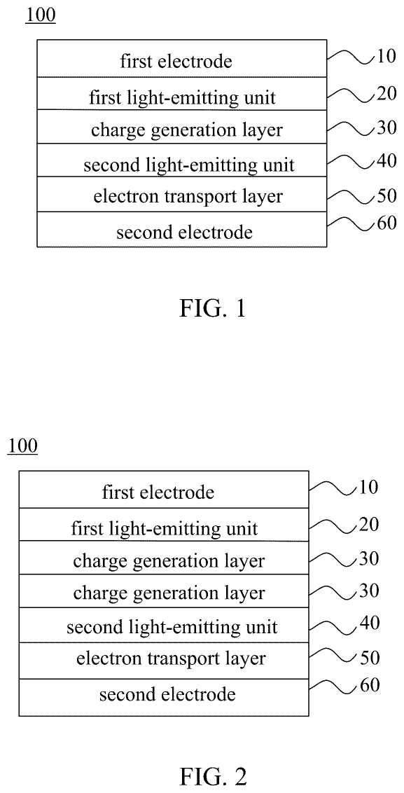

An embodiment of the present disclosure provides a light-emitting device 100. As shown in FIG. 1, the light-emitting device 100 in an embodiment of the present disclosure includes a first electrode 10, a first light-emitting unit 20, one or more charge generation layers 30, a second light-emitting unit 40, an electron transport layer 50 and a second electrode 60 which are stacked in sequence.

In some embodiments of the present disclosure, the first electrode 10 and the second electrode 60 are independently selected from a metal electrode, a carbon electrode, a doped or undoped metal oxide electrode, and a composite electrode. A material of the metal electrode is selected from one or more of Al, Ag, Cu, Mo, Au, Ba, Ca, and Mg. A material of the carbon electrode is selected from one or more of graphite, carbon nanotube, graphene, and carbon fiber. A material of the doped or undoped metal oxide electrode is selected from one or more of ITO, FTO, ATO, AZO, GZO, IZO, MZO, and AMO. A material of the composite electrode is selected from one or more of AZO/Ag/AZO, AZO/Al/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS.

In some embodiments of the present disclosure, the first electrode 10 may be an anode, and the second electrode 60 may be a cathode.

In some embodiments of the present disclosure, a thickness of the first electrode 10 may be 50-110 nm, and may also be 51-60 nm, 61-70 nm, 71-80 nm, 81-90 nm, 91-100 nm, 101-110 nm, etc., or 52 nm, 54 nm, 57 nm, 62 nm, 64 nm, 65 nm, 68 nm, 71 nm, 78 nm, 82 nm, 85 nm, 88 nm, 92 nm, 95 nm, 98 nm, 100 nm, 105 nm, or a range formed by any two values.

In some embodiments of the disclosure, a thickness of the second electrode 60 may be 80-160 nm, and may also be 81-90 nm, 91-100 nm, 101-110 nm, 111-120 nm, 121-130 nm, 131-140 nm, 150-159 nm, etc., or 82 nm, 85 nm, 87 nm, 92 nm, 94 nm, 95 nm, 98 nm, 105 nm, 118 nm, 122 nm, 135 nm, 145 nm, 155 nm, or a range formed by any two of them.

In some embodiments of the disclosure, the first light-emitting unit 20 includes one or more layers of first light-emitting layers arranged in a stack. A material of the first light-emitting layer includes one or more of an organic light-emitting material, a first quantum dot, and a perovskite semiconductor nanoparticle.

In some embodiments of the disclosure, the organic light-emitting material includes one or more of a diaryl anthracene derivative, a stilbene aromatic derivative, a pyrene derivative, a fluorene derivative, a blue-emitting TBPe fluorescent material, a green-emitting TTPA fluorescent material, an orange-emitting TBRb fluorescent material, and a red-emitting DBP fluorescent material.

In some embodiments of the disclosure, the first quantum dot is selected from one or more of a single-structure quantum dot and a core-shell structure quantum dot; a material of the single-structure quantum dot, a core material of the core-shell structure quantum dot, and a shell material of the core-shell structure quantum dot are respectively selected from, but not limited to, one or more of a group II-VI compound, a group IV-VI compound, a group III-V compound, and a group I-III-VI compound.

In some embodiments of the disclosure, the group II-VI compound is selected from, but not limited to, one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe.

In some embodiments of the disclosure, the group IV-VI compound is selected from, but not limited to, one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe.

In some embodiments of the disclosure, the group III-V compound is selected from, but not limited to, one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb.

In some embodiments of the disclosure, the group I-III-VI compound is selected from, but not limited to, one or more of CuInS₂, CuInSe₂, and AgInS₂.

As an example, the core-shell structured quantum dot may be selected from, but not limited to, one or more of CdSe/CdSeS/CdS, InP/ZnSeS/ZnS, CdZnSe/ZnSe/ZnS, CdSeS/ZnSeS/ZnS, CdSe/ZnS, CdSe/ZnSe/ZnS, ZnSe/ZnS, ZnSeTe/ZnS, CdSe/CdZnSeS/ZnS, and InP/ZnSe/ZnS.

In some embodiments of the disclosure, an emission wavelength of the first quantum dot may be 615-625 nm, 535-555 nm, or 465-480 nm.

In some embodiments of the disclosure, the first quantum dot includes one or more of a first red quantum dot, a first green quantum dot, and a first blue quantum dot.

In some embodiments of the disclosure, an emission wavelength of the first red quantum dot may be 615-625 nm, and it may also be 616 nm, 617 nm, 618 nm, 619 nm, 620 nm, 621 nm, 622 nm, 623 nm, 624 nm, or a range defined by any two of the foregoing values. An emission wavelength of the first green quantum dot may be 535-555 nm, and it may also be 536 nm, 537 nm, 539 nm, 540 nm, 542 nm, 543 nm, 545 nm, 547 nm, 549 nm, 550 nm, 551 nm, 554 nm, or a range defined by any two of the foregoing values. An emission wavelength of the first blue quantum dot may be 465-480 nm, and it may also be 466 nm, 467 nm, 468 nm, 470 nm, 472 nm, 474 nm, 475 nm, 476 nm, 478 nm, 479 nm, or a range defined by any two of the foregoing values.

In some embodiments of the present disclosure, a particle size of the first red quantum dot, the first green quantum dot and the first blue quantum dot is independently 5-30 nm, and may be 6, 7, 8, 9, 10, 12, 15, 18, 20, 22, 24, 25, 26, 27, 28, 29 nm or a range formed by any two of them.

In some embodiments of the present disclosure, the perovskite semiconductor nanoparticle is selected from one or more of a doped or non-doped inorganic perovskite semiconductor, or an organic-inorganic hybrid perovskite semiconductor.

In some embodiments of the present disclosure, an average particle size of the perovskite semiconductor nanoparticle is 15-40 nm, or 16-19 nm, 20-25 nm, 26-30 nm, 31-35 nm, etc.

In some embodiments of the present disclosure, the inorganic perovskite semiconductor has a general structure of AMX₃. A is Cs⁺ ion. M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺. X is a halide anion selected from one or more of Cl⁻, Br⁻, I⁻.

In some embodiments of the present disclosure, the organic-inorganic hybrid perovskite semiconductor has a general structure of BMX₃. B is an organic amine cation selected from CH₃(CH₂)ₙ₋₂NH₃⁺ or [NH₃(CH₂)ₙNH₃]²⁺, where n≥2. M is a divalent metal cation selected from one or more of Pb²⁺, Sn², Cu²⁺, Ni²⁺, Cd²⁺, Cr²⁺, Mn²⁺, Co²⁺, Fe²⁺, Ge²⁺, Yb²⁺, Eu²⁺. X is a halide anion selected from one or more of Cl⁻, Br⁻, I⁻.

In some embodiments of the present disclosure, a thickness of the first light-emitting unit 20 may be 10-50 nm, and may be 11-20 nm, 21-30 nm, 31-40 nm, 41-49 nm, etc., or 22 nm, 24 nm, 27 nm, 28 nm, 32 nm, 34 nm, 35 nm, 36 nm, 38 nm, 42 nm, 45 nm, 48 nm or a range formed by any two of them.

In some embodiments of the present disclosure, a material of the charge generation layer 30 is composed of n-type metal oxides. Therefore, each charge generation layer 30 does not contain p-type material.

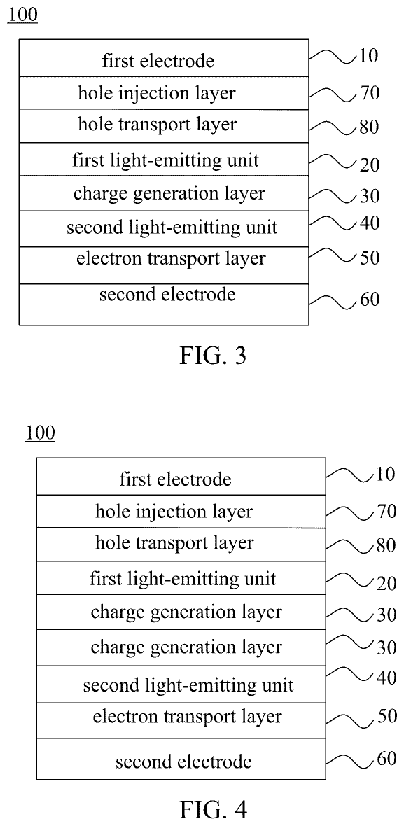

In some embodiments of the present disclosure, a number of the charge generation layer 30 may be 1 to 3. As shown in FIG. 1 and FIG. 3, the light-emitting device 100 therein includes one charge generation layer 30. As shown in FIG. 2 and FIG. 4, the light-emitting device 100 therein includes two charge generation layers 30.

In an embodiment of the present disclosure, a material of the charge generation layer 30 includes an n-type metal oxide, a conduction band minimum energy level of the n-type metal oxide is less than or equal to −3.5 eV and greater than or equal to −5.4 eV. If the conduction band minimum energy level is too large, the charge generation capability of the charge generation layer 30 is weak, the current density of the overall optoelectronic device is too low, and the brightness and efficiency of the optoelectronic device are low. Therefore, in order to ensure the charge generation capability of the charge generation layer 30, it is necessary to have a good energy level matching with the second light-emitting unit 40, that is, the charge generation layer 30 has a deep conduction band minimum energy level and the second light-emitting unit 40 has a shallow valence band maximum energy level, and the difference between the deep conduction band minimum energy level of the charge generation layer 30 and the shallow valence band maximum energy level of the second light-emitting unit 40 is smaller.

In some embodiments of the present disclosure, the material of the charge generation layer 30 is selected from one or more of ZnO, Znₓ₁Mg_{y1}O, Znₓ₁Al_{y1}O, SnO₂, Znₓ₁Sn_{y1}O, and Znₓ₂Mg_{y2}Li_{z2}O. x1+y1=1 or x2+y2+z2=1. When x1+y1=1, 0<x1<1, optionally 0.8<x1<0.95, or 0.85<x1<0.9. When x2+y2+z2=1, 0.8≤x2≤0.95, or 0.85≤x2≤0.9, and a ratio of y2 and z2 is not particularly limited. A content of Zn should not be too low, and a content of doped metal should not be too high, otherwise the electron transport efficiency will be reduced, which is not conducive to the recombination of electrons and holes.

In some embodiments of the present disclosure, a material of the charge generation layer 30 may be selected from one or more of Zn_{0.95}Mg_{0.05}O, Zn_{0.9}Mg_{0.10}, Zn_{0.85}Mg_{0.15}O, Zn_{0.95}Al_{0.05}O, Zn_{0.9}Al_{0.1}O, Zn_{0.85}Al_{0.15}O, Zn_{0.95}Sn_{0.05}O, Zn_{0.9}Sn_{0.1}O, Zn_{0.85}Sn_{0.15}O, and Zn_{0.9}Mg_{0.5}Li_{0.5}O.

In some embodiments of the present disclosure, an average particle size of the material of the charge generation layer 30 may be 4-30 nm, and may also be 5-10 nm, 11-20 nm, 21-25 nm, 26-30 nm, etc., or 22 nm, 23 nm, 24 nm, 25 nm, 26 nm, 28 nm, or a range formed by any two of them.

In some embodiments of the present disclosure, a thickness of the charge generation layer 30 may be 20-60 nm, and may also be 21-25 nm, 26-30 nm, 31-40 nm, 41-50 nm, 51-59 nm, etc., or 22 nm, 24 nm, 27 nm, 28 nm, 32 nm, 34 nm, 35 nm, 36 nm, 38 nm, 42 nm, 45 nm, 48 nm, 52 nm, 53 nm, 55 nm, 57 nm, 58 nm, or a range formed by any two of them.

In some embodiments of the present disclosure, the second light-emitting unit 40 includes one or more second light-emitting layers which are stacked. A material of the second light-emitting layer includes a second quantum dot. In some embodiments, the second quantum dot includes one or more of a second red quantum dot, a second green quantum dot and a second blue quantum dot.

In some embodiments of the present disclosure, an emission wavelength of the second quantum dot may be 615-625 nm, 535-555 nm or 465-480 nm. Specifically, an emission wavelength of the second red quantum dot may be 615-625 nm, and may also be 616 nm, 617 nm, 618 nm, 619 nm, 620 nm, 621 nm, 622 nm, 623 nm, 624 nm or a range formed by any two of the values. In some embodiments, an emission wavelength of the second green quantum dot may be 535-555 nm, and may also be 536 nm, 537 nm, 539 nm, 540 nm, 542 nm, 543 nm, 545 nm, 547 nm, 549 nm, 550 nm, 551 nm, 554 nm or a range formed by any two of the values. In some embodiments, an emission wavelength of the second blue quantum dot may be 465-480 nm, and may also be 466 nm, 467 nm, 468 nm, 470 nm, 472 nm, 474 nm, 475 nm, 476 nm, 478 nm, 479 nm or a range formed by any two of the values. In some embodiments, a particle size of the second red quantum dot, the second green quantum dot and the second blue quantum dot is independently 5-30 nm, and may also be 6, 7, 8, 9, 10, 12, 15, 18, 20, 22, 24, 25, 26, 27, 28, 29 nm or a range formed by any two of the values.

A thickness of the second light-emitting layer may be 10-50 nm, and may also be 11-20 nm, 21-30 nm, 31-40 nm, 41-49 nm, etc., or 22 nm, 24 nm, 27 nm, 28 nm, 32 nm, 34 nm, 35 nm, 36 nm, 38 nm, 42 nm, 45 nm, 48 nm or a range formed by any two of the values.

In some embodiments of the present disclosure, a valence band maximum energy level of the second light-emitting layer is greater than or equal to −5.4 eV and less than −3.5 eV.

In the embodiments of the present disclosure, by adjusting the material (n-type metal oxide) and the conduction band minimum energy level (≤−3.5 eV) of the charge generation layer 30, and the material and the valence band maximum energy level (≥−5.4 eV and <−3.5 eV) of the second light-emitting unit 40, the charge generation layer 30 in embodiments of the present disclosure may play a good charge transmission role without a hole functional layer, and therefore, the structure of the light-emitting device of the present disclosure is relatively simple, and the thickness is thinner than that of the current stacked device (having a hole functional layer and an electron functional layer simultaneously).

The charge generation principle of embodiments of the disclosure is as follows: under the action of an external electric field, carriers are generated at the interface of the charge generation layer 30 and the second light-emitting unit 40, where electrons are injected into the first light-emitting unit 20 through the charge generation layer 30, and holes are injected into the second light-emitting unit 40. The electrons injected into the first light-emitting unit 20 and the holes injected from the first electrode 10 recombine and emit light in the first light-emitting unit 20, and the holes generated by the charge generation layer 30 and the electrons injected from the second electrode 60 recombine and emit light in the second light-emitting unit 40. That is, under the same current density, the simultaneous light emission of the first light-emitting unit 20 and the second light-emitting unit 40 is realized, and the luminous brightness and current efficiency of the light-emitting device 100 are improved.

Embodiments of the disclosure uses an n-type metal oxide as the charge generation layer 30, that is, a material with a certain energy level difference is used to generate charges at the interface. Therefore, embodiments of the disclosure optimizes and selects a suitable material of the second light-emitting unit 40, so that the energy level structure meets the requirements of the charge generation layer 30. In addition, embodiments of the disclosure does not use an n-type electron transport layer 50 and a p-type hole transport layer 80 to form the charge generation layer 30 as in the existing light-emitting device 100, which is equivalent to simplifying the structure of the light-emitting device 100.

In some embodiments of the disclosure, a material of the electron transport layer 50 includes one or more of an inorganic nanocrystalline material, a doped inorganic nanocrystalline material, and an organic material; the inorganic nanocrystalline material includses one or more of zinc oxide, titanium dioxide, tin dioxide, aluminum oxide, calcium oxide, silicon dioxide, gallium oxide, zirconium oxide, nickel oxide, and zirconium sesquioxide; the doped inorganic nanocrystalline material is an inorganic nanocrystalline material containing a doping element, and the doping element is selected from one or more of Mg, Ca, Li, Ga, Al, Co, and Mn; and the organic material includes one or both of polymethyl methacrylate and polyvinyl butyral.

In some embodiments of the disclosure, the material of the electron transport layer 50 is selected from one or more of ZnO, Znₓ₁Mg_{y1}O, Znₓ₁Al_{y1}O, SnO₂, Znₓ₁Sn_{y1}O, and Znₓ₂Mg_{y2}Li_{z2}O, wherein x1+y1=1 or x2+y2+z2=1.

In some embodiments of the disclosure, the material of the electron transport layer 50 is selected from one or more of Zn_{0.95}Mg_{0.050}, Zn_{0.9}Mg_{0.10}, Zn_{0.85}Mg_{0.15}O, Zn_{0.95}Al_{0.05}O, Zn_{0.9}Al_{0.1}O, Zn_{0.85}Al_{0.15}O, Zn_{0.95}Sn_{0.050}, Zn_{0.9}Sn_{0.10}, Zn_{0.85}Sn_{0.15}O, and Zn_{0.9}Mg_{0.5}Li_{0.5}O.

In some embodiments of the disclosure, an average particle size of the material of the electron transport layer 50 is 4-30 nm, and may be 8 nm, 10 nm, 12 nm, 14 nm, 16 nm, 18 nm, 20 nm, 22 nm, 24 nm, 26 nm, or 28 nm.

In some embodiments of the disclosure, a thickness of the electron transport layer 50 may be 20-60 nm, and may be 21-30 nm, 31-40 nm, 41-49 nm, 50-59 nm, etc., or 22 nm, 24 nm, 27 nm, 28 nm, 32 nm, 34 nm, 35 nm, 36 nm, 38 nm, 42 nm, 45 nm, 48 nm, 52 nm, 53 nm, 55 nm, 57 nm, 58 nm, or a range defined by any two of the foregoing values.

In some embodiments of the disclosure, as shown in FIGS. 3 and 4, the light-emitting device 100 further includes a hole functional layer between the first electrode 10 and the first light-emitting unit 20, and the hole functional layer includes a hole injection layer 70 and/or a hole transport layer 80.

In some embodiments of the disclosure, a material of the hole injection layer 70 is a material having hole injection capability. The material of the hole injection layer 70 may be selected from one or more of poly(3,4-ethylenedioxythiophene)-polystyrene sulfonate (PEDOT:PSS), 2,3,5,6-tetrafluoro-7,7′,8,8′-tetracyanoquinodimethane (F4-TCNQ), 2,3,6,7,10,11-hexacyano-1,4,5,8,9,12-hexaazatriphenylene (HATCN), copper phthalocyanine (CuPc), MCC, a transition metal oxide, and a transition metal chalcogenide. The transition metal oxide includes one or more of NiO, MoO₂, WO₃, and CuO; and the transition metal chalcogenide includes one or more of MoS₂, MoSe₂, WS₃, WSe₃, and CuS. A thickness of the hole injection layer 70 may be 10-50 nm, such as 15-20 nm, 20-25 nm, 25-30 nm, 30-40 nm, etc., or a range defined by any two of the foregoing values.

In some embodiments of the present disclosure, a material of the hole transport layer 80 is a material capable of transporting holes. The material of the hole transport layer 80 may be selected from one or more of poly(9,9-dioctylfluorene-CO—N-(4-butylphenyl)diphenylamine) (TFB), polyvinylcarbazole (PVK), poly(N,N′-bis(4-butylphenyl)-N,N′-bis(phenyl)benzidine) (poly-TPD), poly(9,9-dioctylfluorene-co-bis-N,N-phenyl-1,4-phenylenediamine) (PFB), 4,4′,4″-tris(carbazol-9-yl)triphenylamine (TCATA), 4,4′-bis(9-carbazolyl)biphenyl (CBP), N,N′-diphenyl-N,N′-di(3-methylphenyl)-1,1′-biphenyl-4,4′-diamine (TPD), N,N′-diphenyl-N,N′-(1-naphthyl)-1,1′-biphenyl-4,4′-diamine (NPB), poly(3,4-ethylenedioxythiophene)-poly(styrenesulfonate) (PEDOT:PSS), TPH, TAPC (cas: 58473-78-2), Spiro-NPB, Spiro-TPD, doped or undoped NiO, MoO₃, WO₃, V₂O₅, P-type gallium nitride, CrO₃, CuO, MoS₂, MoSe₂, WS₃, WSe₃, CuS, CuSCN. A thickness of the hole transport layer 80 may be 15-50 nm, such as 20-25 nm, 25-30 nm, 30-35 nm, 35-40 nm, 40-45 nm, etc., or a range defined by any two of the foregoing values.

In some embodiments of the present disclosure, the light-emitting device 100 further includes an electron injection layer, which is located between the electron transport layer 50 and the second electrode 60. A material of the electron injection layer includes one or more of LiF/Yb, RbBr, ZnO, Ga₂O₃, Cs₂CO₃, Rb₂CO₃. A thickness of the electron injection layer may be 15-30 nm, such as 20-25 nm, etc.

It can be understood that the light-emitting device 100 can further include some functional layers, such as an electron blocking layer, a hole blocking layer, etc., in addition to the functional layers described above, which are helpful to improve the performance of the light-emitting device 100.

It can be understood that the materials and thicknesses of the layers of the light-emitting device 100 may be set and adjusted according to the light-emitting requirements of the light-emitting device 100.

The light-emitting device 100 further includes a substrate (not shown). The substrate may be a rigid substrate or a flexible substrate. The rigid substrate may be a ceramic material or various glass materials, etc. The flexible substrate may be formed of a substrate made of polyimide film (PI) and its derivatives, polyethylene naphthalate (PEN), phosphoenolpyruvic acid (PEP), or diphenylene ether resin, etc.

It is to be understood that the light-emitting device 100 may be a upright light-emitting device 100 or an inverted light-emitting device. When the light-emitting device 100 is a upright light-emitting device, the substrate is bonded to the side of the anode away from the light-emitting layer. When the light-emitting device is an inverted light-emitting device, the substrate is bonded to the side of the cathode away from the light-emitting layer.

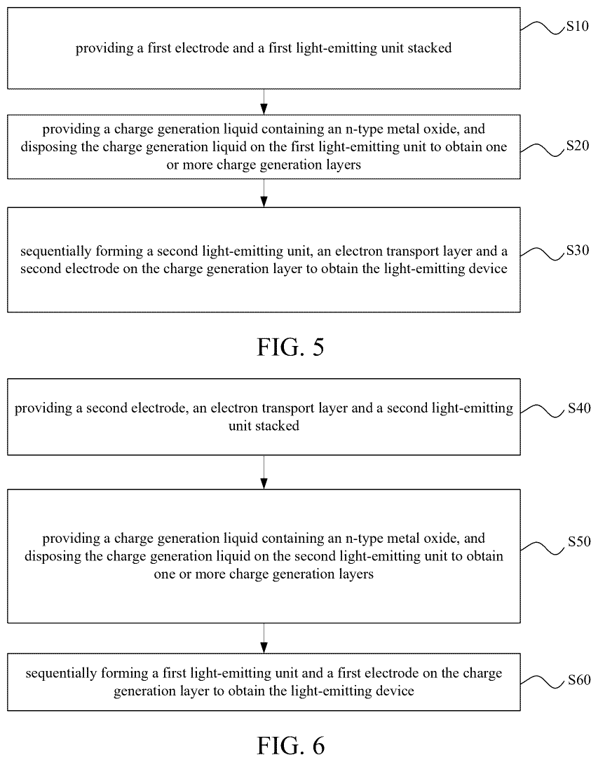

Referring to FIG. 5, the disclosure also provides a method for preparing a light-emitting device, which includes:
S10, providing a first electrode and a first light-emitting unit stacked;
S20, providing a charge generation liquid containing an n-type metal oxide, and disposing the charge generation liquid on the first light-emitting unit to obtain one or more charge generation layers; and
S30, sequentially forming a second light-emitting unit, an electron transport layer and a second electrode on the charge generation layer to obtain the light-emitting device.

Referring to FIG. 6, the disclosure also provides another method for preparing a light-emitting device, which includes:
S40, providing a second electrode, an electron transport layer and a second light-emitting unit stacked;
S50, providing a charge generation liquid containing an n-type metal oxide, and disposing the charge generation liquid on the second light-emitting unit to obtain one or more charge generation layers; and
S60, sequentially forming a first light-emitting unit and a first electrode on the charge generation layer to obtain the light-emitting device.

In some embodiments, after the charge generation liquid is disposed on the first light-emitting unit or the second light-emitting unit, a drying process may be further performed to remove the solvent, thereby obtaining the desired charge generation layer. If a plurality of charge generation layers are needed, the above steps may be repeated to obtain the plurality of charge generation layers.

In some embodiments, a number of the charge generation layers is 1 to 3.

In some embodiments, a material of the charge generation layer includes an n-type metal oxide, and the conduction band minimum energy level of the n-type metal oxide is less than or equal to −3.5 eV.

In some embodiments, the material of the charge generation layer is selected from one or more of ZnO, Znₓ₁Mg_{y1}O, Znₓ₁Al_{y1}O, SnO₂, Znₓ₁Sn_{y1}O, Znₓ₂Mg_{y2}Li_{z2}O, x1+y1=1 or x2+y2+z2=1.

In some embodiments, the second light-emitting unit includes one or more second light-emitting layers stacked. A material of the second light-emitting layer includes a second quantum dot, the material of the second quantum dot is selected from one or more of InN, InP, InAs, InSb, InPAs, InPSb, copper indium sulfide (CIS), copper indium gallium sulfide (CIGS), zinc copper indium sulfide (ZCIS), a valence band maximum energy level of the second light-emitting layer is greater than or equal to −5.4 eV and less than −3.5 eV.

Specifically, a method for forming the functional layers may be a chemical method or a physical method. The functional layers include, but are not limited to, a cathode, a light-emitting layer, a cathode, a hole functional layer, and an electron functional layer. The chemical method includes chemical vapor deposition, successive ion layer adsorption and reaction, anodic oxidation, electrolytic deposition, and co-precipitation. The physical method includes physical coating and a solution method. The physical coating includes thermal evaporation coating, electron beam evaporation coating, magnetron sputtering, multi-arc ion coating, physical vapor deposition, atomic layer deposition, pulsed laser deposition, and the like. The solution method may be spin coating, printing, inkjet printing, blade coating, printing, dip coating, soaking, spraying, rolling, casting, slot coating, stripe coating, and the like.

The disclosure also provides a display device including the light-emitting device as described in any of the above embodiments or prepared by the method for preparing the light-emitting device according to any of the above embodiments. The display device may be an electronic product with a display function, including but not limited to a smart phone, a tablet computer, a notebook computer, a digital camera, a digital video camera, a smart wearable device, a smart weighing electronic scale, a vehicle-mounted display, a television, or an electronic book reader. The smart wearable device may be, for example, a smart bracelet, a smart watch, a virtual reality (VR) helmet, or the like.

The disclosure is described in detail below with reference to specific examples. The following examples are only part of the disclosure and do not limit the disclosure. The related properties of the light-emitting layers and light-emitting devices of the following Examples and Comparative Examples are tested by the following methods, and the test results are shown in Table 1.

1. The test methods of current efficiency and turn-on voltage are as follows.

A current ID is applied to the light-emitting device, and the light-emitting device is excited at an area A, and the light-emitting brightness L is measured. The current efficiency can be calculated by the formula:

$$η c = LA / ID$$

wherein ηc is the current efficiency at the brightness L, and the standard unit is cd/A.

The turn-on voltage is the driving voltage corresponding to the light-emitting brightness of 1 cd/m2, and the standard unit is V.

### Example 1

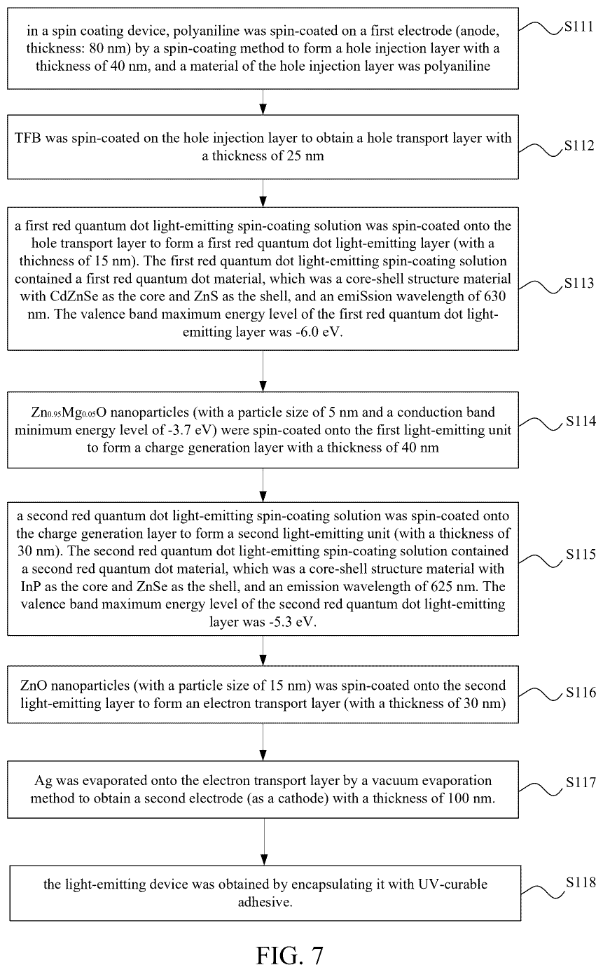

Referring to FIG. 7, Example 1 provides a method for preparing a light-emitting device (i.e., a quantum dot light-emitting diode), specifically including the following steps.
S111, in a spin coating device, polyaniline was spin-coated on a first electrode (anode, thickness: 80 nm) by a spin-coating method to form a hole injection layer with a thickness of 40 nm. A material of the hole injection layer was polyaniline.
S112, TFB was spin-coated on the hole injection layer to obtain a hole transport layer with a thickness of 25 nm.
S113. a first red quantum dot light-emitting spin-coating solution was spin-coated onto the hole transport layer to form a first red quantum dot light-emitting layer (with a thichness of 15 nm). The first red quantum dot light-emitting spin-coating solution contained a first red quantum dot material, which was a core-shell structure material with CdZnSe as the core and ZnS as the shell, and an emission wavelength of 630 nm. The valence band maximum energy level of the first red quantum dot light-emitting layer was −6.0 eV.
S114. Zn_{0.95}Mg_{0.05}O nanoparticles (with a particle size of 5 nm and a conduction band minimum energy level of −3.7 eV) were spin-coated onto the first light-emitting unit to form a charge generation layer with a thickness of 40 nm.
S115. a second red quantum dot light-emitting spin-coating solution was spin-coated onto the charge generation layer to form a second light-emitting unit (with a thickness of 30 nm). The second red quantum dot light-emitting spin-coating solution contained a second red quantum dot material, which was a core-shell structure material with InP as the core and ZnSe as the shell, and an emission wavelength of 625 nm. The valence band maximum energy level of the second red quantum dot light-emitting layer was −5.3 eV.
S116. ZnO nanoparticles (with a particle size of 15 nm) was spin-coated onto the second light-emitting layer to form an electron transport layer (with a thickness of 30 nm).
S117. Ag was evaporated onto the electron transport layer by a vacuum evaporation method to obtain a second electrode (as a cathode) with a thickness of 100 nm.
S118. the light-emitting device was obtained by encapsulating it with UV-curable adhesive.

The structure of the light-emitting device in this embodiment was: first electrode (anode)/hole injection layer/hole transport layer/first light-emitting unit/charge generation layer/second light-emitting unit/electron transport layer/second electrode (cathode).

### Example 2

The difference between Example 2 and Example 1 is that the light-emitting device of Example 2 does not have a hole injection layer and a hole transport layer, that is, steps 1 and 2 of Example 1 were cancelled, and therefore, the structure of the light-emitting device in this Example was: first electrode (anode)/first light-emitting unit/charge generation layer/second light-emitting unit/electron transport layer/second electrode (cathode).

The test result shows that if there is no hole injection layer and hole transport layer, because the first light-emitting unit has a deeper valence band maximum energy level, if there is no hole injection layer or hole transport layer, the hole injection effect is poor, the light-emitting efficiency of the device is low, and the turn-on voltage is high.

### Examples 3 to 5

The difference between Examples 3 to 5 and Example 1 is that the materials of the charge generation layers are different. The material of the charge generation layer of Example 1 is Zn_{0.95}Mg_{0.05}ZnO nanoparticles, with a particle size of 5 nm and a conduction band minimum energy level of −3.7 eV.

A material of the charge generation layer of Example 3 is Zn_{0.85}Mg_{0.15}O nanoparticles, with a particle size of 4.5 nm, and a conduction band minimum energy level of −3.9 eV.

A material of the charge generation layer of Example 4 is Zn_{0.95}Sn_{0.05}O nanoparticles, with a particle size of 8 nm, and a conduction band minimum energy level of −4.0 eV.

A material of the charge generation layer of Example 5 is a mixture of Zn_{0.95}Sn_{0.05}O nanoparticles (with a particle size of 8 nm) and Zn_{0.95}Mg_{0.05}ZnO nanoparticles (with a particle size of 5 nm), with a conduction band minimum energy level of −3.8 eV.

The test results show that the deeper the conduction band minimum energy level of the charge generation layer, the smaller the valence band maximum energy level difference with the second light-emitting unit, the more conducive to the separation of electrons and holes, and the lower the driving voltage and the higher the luminous efficiency of the light-emitting device.

### Examples 6 to 7

Examples 6 to 7 differ from Example 1 only in that the materials of the second light-emitting layers are different. In Example 6, the material of the second red quantum dot is copper indium sulfide (CIS), with an emission wavelength of 625 nm. In Example 7, the material of the second red quantum dots is zinc copper indium sulfide (ZCIS) and InP, with an emission wavelength of 620 nm.

The test results show that when the second light-emitting unit contains copper indium sulfide (CIS), the charge generation capacity of the charge generation layer is increased and the driving voltage of the light-emitting device is reduced due to the shallower valence band maximum energy level of copper indium sulfide (CIS). When the material of the second red quantum dots is zinc copper indium sulfide (ZCIS) and InP, the zinc copper indium sulfide (ZCIS) has a shallower valence band maximum energy level, and InP has high performance, so the charge generation capacity is increased and the performance of the second light-emitting unit is increased.

### Comparative Example 1

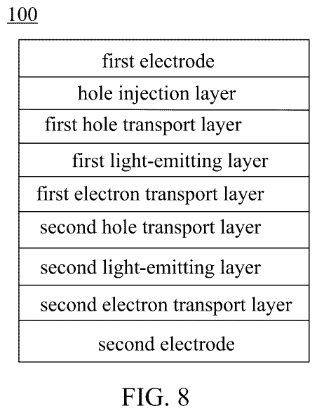

FIG. 8 is a schematic structural diagram of the structure of the light-emitting device of Comparative Example 1. Comparative Example 1 differs from Example 1 only in that the structure and the material of the charge generation layer are different. Example 1 has a charge generation layer between the two light-emitting units, while the charge generation layer of Comparative Example 1 includes a second hole transport layer, a second light-emitting layer and a second electron transport layer stacked together, so the thickness of the light-emitting device of Comparative Example 1 is higher than that of the light-emitting device in the Examples of the present disclosure, the luminous efficiency is lower than that of the light-emitting device in Example 1, and the turn-on voltage is higher than that of the light-emitting device in the Examples of the present disclosure.

### Examples 8 to 10

Examples 8 to 10 differ from Example 1 only in that the energy level relationship of the first red quantum dot light-emitting layer, the charge generation layer and the second red quantum dot light-emitting layer (with a thickness of 30 nm) is adjusted.

In Example 1, the material of the first red quantum dot light-emitting layer (with a thickness of 15 nm) is quantum dots having CdZnSe as the core and CdSe as the shell. The emission wavelength is 630 nm, and the valence band maximum energy level is −6.0 eV. The material of the charge generation layer (with a thickness of 40 nm) is Zn_{0.95}Mg_{0.05}O nanoparticles (with a particle size of 5 nm, and a conduction band minimum energy level of −3.7 eV). The material of the second red quantum dot light-emitting layer (with a thickness of 30 nm) is quantum dots having InP as the core and ZnSe as the shell, the emission wavelength is 626 nm, and the valence band maximum energy level is −5.3 eV.

In Example 8, the material of the first red quantum dot light-emitting layer (with a thickness of 15 nm) is quantum dots having CdZnSe as the core and ZnS as the shell, the emission wavelength is 630 nm, and the valence band maximum energy level is −6.0 eV. The material of the charge generation layer (with a thickness of 40 nm) is ZnO nanoparticles (with a particle size of 5 nm, and a conduction band minimum energy level of −3.5 eV). The material of the second red quantum dot light-emitting layer (with a thickness of 30 nm) is quantum dots having InP as the core and ZnSe as the shell, the emission wavelength is 626 nm, and the valence band maximum energy level is −5.4 eV.

In Example 9, the material of the first red quantum dot light-emitting layer (with a thickness of 15 nm) is quantum dots having CdZnSe as the core and ZnS as the shell, the emission wavelength is 630 nm, and the valence band maximum energy level is −6.0 eV. The material of the charge generation layer (with a thickness of 40 nm) is SnO₂ nanoparticles (with a particle size of 8 nm, and a conduction band minimum energy level of −4.2 eV). The material of the second red quantum dot light-emitting layer (with a thickness of 30 nm) is quantum dots having copper indium sulfide (CIS) as the core and ZnS as the shell, the emission wavelength is 626 nm, and the valence band maximum energy level is −4.8 eV.

In Example 10, the material of the first red quantum dot light-emitting layer (with a thickness of 15 nm) is quantum dots having CdZnSe as the core and ZnS as the shell, the emission wavelength is 630 nm, and the valence band maximum energy level is −6.0 eV. The material of the charge generation layer (with a thickness of 40 nm) is ZnO nanoparticles (with a particle size of 10 nm, and a conduction band minimum energy level of −3.2 eV). The material of the second red quantum dot light-emitting layer (with a thickness of 30 nm) is quantum dots having copper indium sulfide (CIS) as the core and ZnS as the shell, the emission wavelength is 626 nm, and the valence band maximum energy level is −4.8 eV.

According to the test results, the charge generation layer in the above examples is conducive to the recombination of holes and electrons by matching the energy levels and materials of the first light-emitting unit, the charge generation layer, and the second light-emitting unit, without the need to additionally add a hole transport layer in the charge generation layer, thereby reducing the thickness of the light-emitting device without affecting the light-emitting intensity. If the conduction band minimum energy level of the charge generation layer is greater than −3.5 eV, then its energy level matching with the second light-emitting unit will not be ideal. This will reduce the carrier generation efficiency, thereby degrading the performance of the light-emitting device.

TABLE 1

| | Luminescent efficiency | Turn-on voltage |
|---|---|---|
| items | (cd/A) | (V) |
| Example 1 | 14.0 | 11.5 |
| Example 2 | 6.0 | 22.0 |
| Example 3 | 15.0 | 10.5 |
| Example 4 | 15.5 | 9.4 |
| Example 5 | 13.0 | 9.9 |
| Example 6 | 11.5 | 9.1 |
| Example 7 | 12.0 | 9.2 |
| Comparative Example 1 | 8.5 | 11.8 |
| Example 8 | 12.0 | 14.5 |
| Example 9 | 9.5 | 13.0 |
| Example 10 | 8.3 | 21.0 |

The above detailed description of the disclosure is provided, and the principle and implementation mode of the disclosure are described by using specific examples. The above examples are only used to help understand the method and core idea of the disclosure. Meanwhile, for those skilled in the art, the specific implementation mode and disclosure range can be changed according to the idea of the disclosure. In conclusion, the content of the specification should not be understood as a limitation of the disclosure.

1. A light-emitting device comprising:
a first electrode, a first light-emitting unit, one or more charge generation layers, a second light-emitting unit, an electron-transporting layer, and a second electrode, which are sequentially stacked;
wherein a material of the charge generation layer comprises an n-type metal oxide.

2. The light-emitting device according to claim 1, wherein the material of the charge generation layer consists of the n-type metal oxide.

3. The light-emitting device according to claim 1, wherein the material of the charge generation layer is selected from one or more of ZnO, Znₓ₁Mg_{y1}O, Znₓ₁Al_{y1}O, SnO₂, Znₓ₁Sn_{y1}O, and Znₓ₂Mg_{y2}Li_{z2}O, where x1+y1=1 or x2+y2+z2=1.

4. The light-emitting device according to claim 3, wherein for x1+y1=1, 0.8<x1<0.95; and/of
$$for x 2 + y 2 + z 2 = 1 , 0.8 < x 2 < 0.95 .$$

5. The light-emitting device according to claim 3, wherein the material of the charge generation layer is selected from one or more of Zn_{0.95}Mg_{0.05}O, Zn_{0.9}Mg_{0.1}O, Zn_{0.85}Mg_{0.150}, Zn_{0.95}Al_{0.05}O, Zn_{0.9}Al_{0.1}O, Zn_{0.85}Al_{0.15}O, Zn_{0.95}Sn_{0.05}O, Zn_{0.9}Sn_{0.1}O, Zn_{0.85}Sn_{0.15}O, and Zn_{0.9}Mg_{0.5}Li_{0.5}O.

6. The light-emitting device according to claim 1, wherein a number of the charge generation layers is 1 to 3;
a thickness of the charge generation layer is 20-60 nm;
an average particle size of the material of the charge generation layer is 4-30 nm.

7. The light-emitting device according to claim 1, wherein a conduction band minimum energy level of the n-type metal oxide is less than or equal to −3.5 eV;
a valence band maximum energy level of the second light-emitting unit is greater than or equal to −5.4 eV and less than −3.5 eV.

8. The light-emitting device according to claim 1, wherein the first light-emitting unit and the second light-emitting unit independently comprise one or more light-emitting layers which are stacked.

9. The light-emitting device according to claim 8, wherein the second light-emitting unit comprises a second light-emitting layer, and a material of the second light-emitting layer comprises a second quantum dot;
a thickness of the second light-emitting unit is 10-50 nm.

10. The light-emitting device according to claim 9, wherein a material of the second quantum dot comprises one or more of InN, InP, InAs, InSb, InPAs, InPSb, copper indium sulfide, copper indium gallium sulfide, zinc copper indium sulfide.

11. The light-emitting device according to claim 9, wherein an emission wavelength of the second quantum dot is 615-625 nm;
an emission wavelength of the second quantum dot is 535-555 nm;
an emission wavelength of the second quantum dot is 465-480 nm; and/of
an average particle size of the second quantum dot is 5-30 nm.

12. The light-emitting device according to claim 1, wherein the first light-emitting unit comprises a first light-emitting layer, and a material of the first light-emitting layer comprises one or more of an organic light-emitting material, a first quantum dot, and a perovskite semiconductor nanoparticle; and
a thickness of the first light-emitting unit is 10-50 nm.

13. The light-emitting device according to claim 12, wherein the organic light-emitting material comprises one or more of a diaryl anthracene derivative, a stilbene aromatic derivative, a pyrene derivative, or a fluorene derivative, a blue light-emitting TBPe fluorescent material, a green light-emitting TTPA fluorescent material, an orange light-emitting TBRb fluorescent material, and a red light-emitting DBP fluorescent material;
the first quantum dot is selected from one or more of a single-structure quantum dot and a core-shell structure quantum dot; a material of the single-structure quantum dot, a core material of the core-shell structure quantum dot, and a shell material of the core-shell structure quantum dot are respectively selected from one or more of a group II-VI compound, a group IV-VI compound, a group III-V compound, and a group I-III-VI compound; wherein the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe; the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; and the group I-III-VI compound is selected from one or more of CuInS₂, CuInSe₂, and AgInS₂;
the perovskite semiconductor nanoparticle is selected from one or more of a doped or non-doped inorganic perovskite semiconductor or an organic-inorganic hybrid perovskite semiconductor; wherein the inorganic perovskite semiconductor has a general structure of AMX₃, wherein A is a Cs⁺ ion, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is a halide anion selected from one or more of Cl⁻, Br⁻, I⁻; the organic-inorganic hybrid perovskite semiconductor has a general structure of BMX₃, wherein B is an organic amine cation selected from CH₃(CH₂)ₙ₋₂NH₃⁺ or [NH₃(CH₂)ₙNH₃]²⁺ where n≥2, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is a halide anion selected from one or more of Cl⁻, Br⁻, I⁻;
an average particle size of the first quantum dot is 5-30 nm;
an average particle size of the perovskite semiconductor nanoparticle is 15-40 nm.

14. The light-emitting device according to claim 1, wherein the first electrode and the second electrode are independently selected from a metal electrode, a carbon electrode, a doped or non-doped metal oxide electrode, and a composite electrode; the metal electrode is made of one or more of Al, Ag, Cu, Mo, Au, Ba, Ca, and Mg; the carbon electrode is made of one or more of graphite, carbon nanotube, graphene, and carbon fiber; the doped or non-doped metal oxide electrode is made of one or more of ITO, FTO, ATO, AZO, GZO, IZO, MZO, and AMO; and the composite electrode is made of one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS;
a material of the electron transport layer comprises one or more of an inorganic nanocrystalline material, a doped inorganic nanocrystalline material and an organic material; the inorganic nanocrystalline material comprises one or more of zinc oxide, titanium dioxide, tin dioxide, aluminum oxide, calcium oxide, silicon dioxide, gallium oxide, zirconium oxide, nickel oxide and zirconium sesquioxide; the doped inorganic nanocrystalline material is an inorganic nanocrystalline material containing a doping element, and the doping element is selected from one or more of Mg, Ca, Li, Ga, Al, Co and Mn; and the organic material comprises one or both of polymethyl methacrylate and polyvinyl butyral; or the material of the electron transport layer is selected from one or more of ZnO, Znₓ₁Mg_{y1}O, Znₓ₁Al_{y1}O, SnO₂, Znₓ₁Sn_{y1}O and Znₓ₂Mg_{y2}Li_{z2}O, x1+y1=1 or x2+y2+z2=1;
a thickness of the electron transport layer is 20-60 nm.

15. The light-emitting device according to claim 1, wherein the light-emitting device further comprises a hole functional layer between the first electrode and the first light-emitting unit, the hole functional layer comprising one or both of a hole injection layer and a hole transport layer, and when the hole functional layer comprises the hole injection layer and the hole transport layer, the hole injection layer is disposed on the side close to the first electrode, and the hole transport layer is disposed on the side close to the first light-emitting unit;
the light-emitting device further comprises an electron injection layer between the electron transport layer and the second electrode, and disposed on the side close to the second electrode;
the first electrode is an anode;
a thickness of the first electrode is 50-110 nm;
the second electrode is a cathode;
a thickness of the second electrode is 80-160 nm.

16. The light-emitting device according to claim 15, wherein a material of the hole injection layer is selected from one or more of PEDOT:PSS, F4-TCNQ, HATCN, CuPc, MCC, a transition metal oxide and a transition metal chalcogenide; wherein the transition metal oxide comprises one or more of NiO, MoO₂, WO₃ and CuO; and the transition metal chalcogenide comprises one or more of MoS₂, MoSe₂, WS₃, WSe₃ and CuS;
a thickness of the hole injection layer is 10-50 nm;
a material of the hole transport layer is selected from one or more of TFB, PVK, poly-TPD, PFB, TCATA, CBP, TPD, NPB, PEDOT:PSS, TPH, TAPC, Spiro-NPB, Spiro-TPD, doped or undoped NiO, MoO₃, WO₃, V₂O₅, P-type gallium nitride, CrO₃, CuO, MoS₂, MoSe₂, WS₃, WSe₃, CuS, and CuSCN;
a thickness of the hole transport layer is 15-50 nm;
a material of the electron injection layer comprises one or more of LiF/Yb, RbBr, ZnO, Ga₂O₃, Cs₂CO₃, and Rb₂CO₃; and
a thickness of the electron injection layer is 15-30 nm.

17. A method for preparing a light-emitting device, wherein,
the method comprises:
providing a first electrode and a first light-emitting unit stacked;
providing a charge generation liquid containing an n-type metal oxide, and disposing the charge generation liquid on the first light-emitting unit to obtain one or more charge generation layers; and
forming a second light-emitting unit, an electron transport layer and a second electrode on the charge generation layer in sequence to obtain the light-emitting device.

18. The method according to claim 17 wherein a material of the charge generation layer comprises an n-type metal oxide, and a conduction band minimum energy level of the n-type metal oxide is less than or equal to −3.5 eV;
a valence band maximum energy level of the second light-emitting unit is greater than or equal to −5.4 eV and less than −3.5 eV.

19. The method according to claim 17, wherein a material of the charge generation layer is selected from one or more of ZnO, Znₓ₁Mg_{y1}O, Znₓ₁Al_{y1}O, SnO₂, Znₓ₁Sn_{y1}O, and Znₓ₂Mg_{y2}Li_{z2}O, wherein x1+y1=1 or x2+y2+z2=1;
the first light-emitting unit comprises a first light-emitting layer, and a material of the first light-emitting layer comprises one or more of an organic light-emitting material, a first quantum dot, and a perovskite semiconductor nanoparticle; and
the second light-emitting unit comprises a second light-emitting layer, a material of the second light-emitting layer comprises a second quantum dot, comprising one or more of InN, InP, InAs, InSb, InPAs, InPSb, copper indium sulfide, copper indium gallium sulfide, and zinc copper indium sulfide.

20. (canceled)

21. A method for preparing a light-emitting device, wherein,
the method comprises:
providing a second electrode, an electron transport layer and a second light-emitting unit stacked;
providing a charge generation liquid containing an n-type metal oxide, and disposing the charge generation liquid on the second light-emitting unit to obtain one or more charge generation layers; and
forming a first light-emitting layer and a first electrode on the charge generation layer in sequence to obtain the light-emitting device.
